(19) United States
(12) Patent Application Publication
(10) Pub. No.: US 2003/0148022 A1
(43) Pub. Date: Aug. 7, 2003

(54) Manufacturing method for organic EL element, organic EL transfer member, and member to be transferred

(76) Inventor: Hiroshi Kishimoto, Tokyo (JP)

Correspondence Address: WILDMAN, HARROLD, ALLEN & DIXON, 225 WEST WACKER DRIVE, CHICAGO, IL, 60606, US

(21) Appl. No.: 10/323,331

(22) Filed: Dec. 18, 2002

(30) Foreign Application Priority Data
Dec. 20, 2001 (JP) 2001-387199

(51) Int. Cl. B05D 5/12

(52) U.S. Cl. 427/68; 427/66

(57) ABSTRACT

The main object of the present invention is to provide a method for easily producing a high quality organic EL element by the transfer at a relatively low temperature, an organic EL transfer member and a member to be transferred used therefore. In order to achieve the above-described object, in the present invention, a method; using a transfer member having at least a supporting member and a light emitting layer formed peelably on the supporting member and a member to be transferred having at least a base member and an electrode formed on the base member; comprising a process of superimposing the light emitting layer side of the transfer member and the electrode side of the member to be transferred, and partially transferring at least the light emitting layer from the transfer member onto the member to be transferred; wherein a bonding property improving substance is included in at least one of the layer of the transfer member in contact with the member to be transferred or the layer of the member to be transferred in contact with the transfer member is provided.

### BACKGROUND OF THE INVENTION

1. Field of the Invention

The present invention relates to a manufacturing method for an organic EL element using a transfer method, an organic EL transfer member and a member to be transferred used therefor.

2. Description of the Related Art

An organic EL element is a self light emission type element having advantages such as a wide view angle, the capability of low voltage drive, a high luminance, and a smaller number of constituent layers compared with a liquid crystal element so that easily manufactured and easily made thinner. Such an organic EL element attracts the attention as a new display element for the liquid crystal display, and at the time of producing the color display element, the selective formation of an organic EL material for emitting each color in a fine pattern has been the important technological problem.

Nowadays, as a method for manufacturing a color display element using such an organic EL element, three kinds of methods are known. First one is a method of using an organic EL material emitting a white color light and a color filter in a combination. Second one is a color conversion method of using an organic EL element emitting a blue color light and color conversion layers for converting the blue color of the element into a red color and a green color. Third one is a method of disposing each organic EL materials independently for emitting red (R), green (G) and blue (B) colors. Among the three kinds of methods, the method capable of utilizing the light emission of the organic EL elements most efficiently is the third method. In the first and second methods, the light emission utilization efficiency is about one-third of that in the third method, and thus it is extremely low utilization efficiency.

However, in the third method, since the organic EL material in general is easily damaged in a wet process, there is a problem that a fine resolution using a photolithography technique can hardly be realized. Therefore, in order to independently dispose R, G, and B in the third method, a vapor deposition method using a shadow mask is used commonly. However, there are many problems in this method such that the fine processing of the shadow mask is difficult, the accurate vapor deposition film formation is difficult due to the extension and contraction distortion of the shadow mask, or the spread of the vapor deposition to the periphery, derived from the thinness of the shadow mask in the case of a fine shadow mask pattern.

Moreover, in the third method, the fine pattern coating distinction by the transfer of the organic EL light emitting material is disclosed in Japanese Patent Application Laid-Open (JP-A) No. 12-011216, No. 12-077182, or the like. However, these methods are basically of the sublimation transfer methods for transferring the light emitting material by sublimation. At the time of forming a sublimating light emitting material on a transfer member, vapor deposition is needed. It is a method suitable in the case of using a low molecular weight material among the organic EL materials, however, it is not suitable in the case of using a polymer material. Moreover, similarly, the above-mentioned R, G, B patterning method by the vapor deposition using the shadow mask is suitable in the case of using a low molecular weight material, but it is not suitable in the case of using a polymer material. Furthermore, in the sublimation transfer, the sublimated material is scattered so as to spread to a non-formation part that generates the problems such as color mixture.

Moreover, a manufacturing method for an organic EL element by transferring other than the sublimation transfer method, such as melting transfer, is a labor taking method. For example, as disclosed in the Japanese Patent Application Laid-Open (JP-A) No. 12-011216, a protruding projection is formed on a high temperature conductive sheet and an organic material is formed thereon, for producing a transfer member, so that much labor is required for producing the transfer member. Furthermore, the method disclosed in the Japanese Patent Application Laid-Open (JP-A) No. 12-077182 is not a satisfactory transfer method due to difficulty of production of the transfer member because the transfer member comprises a lattice-like or band-like low temperature conductive part and a high temperature conductive part inside thereof. In particular, an effective method as a manufacturing method for a color display element using a polymer organic EL material has not been proposed so far.

In a method for manufacturing an organic EL element by transfer, in the case the transfer member comprises a supporting member/a peeling layer containing light heat converting substance/organic EL transfer layer (organic light emitting layer), not only the organic EL transfer layer but also the peeling layer may often be transferred together due to the transfer characteristic of the layer in contact with the organic EL transfer layer and the member to be transferred. In the case the peeling layer is transferred together, even if a cathode is formed after the transfer for manufacturing an EL element, light emission cannot be obtained or the light emitting characteristic is drastically deteriorated. In reality, the area with the transfer condition (concerning the parameters such as the temperature, the quantity of light and the transfer speed), having only the EL material transferred onto the member to be transferred, is an extremely slight area, or such an area does not exist so that a highly efficient EL element manufacturing by the transfer is extremely difficult. If the area is small, the productivity and the yield are lowered due to various external irregularity factors, or a problem is involved in that the manufacturing condition setting is difficult so that existence and expansion of the area are required.

Moreover, a polymer organic EL material is weak to the heat. In the case heat of a glass transition point or higher is applied, the light emitting characteristic is deteriorated. At a temperature of rubber elasticity area or higher, it is remarkably deteriorated, and furthermore, the element life is lowered in the case an organic EL element is produced. However, in the case a polymer organic EL material is used for an organic EL transfer member and a member to be transferred, a transfer operation cannot be enabled unless heat is applied to the vicinity of the rubber elasticity area of the material used for the transfer member or the member to be transferred, and a problem arises in that the lifetime and the light emitting characteristic of the organic EL element are lowered inevitably due to the transfer.

### SUMMARY OF THE INVENTION

An object of the present invention is to provide a simple manufacturing method capable of obtaining a high quality organic EL element without deterioration of the lifetime or the light emitting efficiency even in the case a polymer material weak to the heat is used for the organic EL material by realizing a manufacturing method by the transfer of an organic EL at a relatively low temperature, an organic EL transfer member used for the production, and a member to be transferred.

The present inventor has found out that the above-mentioned object can be achieved by adding a bonding property improving substance to the layer of the transfer member of the organic EL transfer member in contact with the member to be transferred (uppermost layer), or adding a bonding property improving substance to the layer of the member to be transferred in contact with the transfer member (uppermost layer).

Accordingly, a manufacturing method for an organic EL element of the present invention; uses a transfer member, having at least a supporting member and a light emitting layer formed peelably on the supporting member, and a member to be transferred, having at least a base member and an electrode formed on the base member; comprising a process of superimposing the light emitting layer side of the transfer member and the electrode side of the member to be transferred, and partially transferring at least the light emitting layer from the transfer member onto the member to be transferred; wherein a bonding property improving substance is included in at least one of the layer of the transfer member in contact with the member to be transferred or the layer ot the member to be transferred in contact with the transfer member.

According to the present invention, a manufacturing method for an organic EL by the transfer at a relatively low temperature can be realized. A manufacturing method for an organic EL element capable of obtaining a high quality organic EL element easily with little deterioration of the lifetime or the light emitting efficiency even in the case a polymer material weak to the heat is used for the organic EL material, an organic EL transfer member used for the production, and a member to be transferred can be provided. Particularly in the case the laser transfer is executed using an organic EL transfer member having a peeling layer and a light heat converting layer, the condition range for peeling only the organic EL transfer layer off can be provided or widened so as to facilitate or enable production of an element by the laser transfer.

### BRIEF DESCRIPTION OF THE DRAWING

FIG. 1 is a diagram showing an embodiment of a manufacturing method for an organic EL element of the present invention.

### DESCRIPTION OF THE PREFERRED EMBODIMENTS

Manufacturing Method for an Organic EL Element:

(Manufacturing Method)

A manufacturing method for an organic EL element of the present invention is a method using a transfer method, where a bonding property improving substance is included in at least one of the layers to be contacted at the time of transfer. Then, the transfer member comprises at least a supporting member and a light emitting layer formed peelably on the supporting member. The member to be transferred comprises at least a base member and an electrode formed on the base member. Except for this transfer process, it can be manufactured by a common manufacturing method for an EL element.

(Organic EL Element Manufactured by a Method of the Present Invention)

An organic EL element manufactured by a method of the present invention comprises at, least for, example an electrode and an organic EL layer having a light emitting layer formed on the electrode, and another electrode formed on the organic EL layer. Although the organic EL layer may comprise a single layer of a light emitting layer, it is preferable to provide a multi layer structure in addition to an optional combination with a hole transporting layer, an electron transporting layer, or the like. Moreover, a light blocking layer such as a black matrix may be provided between the pixels. Furthermore, a full color organic EL element can be manufactured preferably by transferring three kinds of organic EL transfer members having organic light emitting materials to emit a light of each color of R, G, B as the organic EL transfer layers to a position corresponding to each color of a member to be transferred.

(Structure of the Organic EL Transfer Member and the Member to be Transferred)

An organic EL transfer member provided in an organic EL transfer member used for manufacturing of such an organic EL element comprises at least a light emitting layer including an organic light emitting material. Furthermore, a bonding property improving substance is included in at least one of the layer of the transfer member to be contacted with the member to be transferred or the layer of the member to be transferred to be contacted with the transfer member.

As the manufacturing method for an organic EL element with the structure of the organic EL transfer member and the member to be transferred, the following can be presented:

(1) The organic EL transfer member comprises a supporting member/a peeling layer/an electron injecting layer/an organic EL light emitting layer, and the organic EL member to be transferred comprises a base member/a first electrode/a hole transporting layer (with a bonding property improving substance added to the light emitting layer and/or the hole transporting layer). The organic EL element is manufactured by transferring the organic EL light emitting layer and the electron injecting layer on the hole transporting layer, and forming the second electrode on the electron injecting layer.

(2) The organic EL transfer member comprises a supporting member/a peeling layer/an organic EL light emitting layer, and the organic EL member to be transferred comprises a base member/a first electrode/a hole transporting layer (with a bonding property improving substance added to the light emitting layer and/or the hole transporting layer). The organic EL element is manufactured by transferring the organic EL light emitting layer on the hole transporting layer, forming the electron injecting layer on the organic EL light emitting layer, and further forming the second electrode on the electron injecting layer.

(3) The organic EL transfer member comprises a supporting member/a peeling layer/a hole transporting layer/an organic EL light emitting layer, and the organic EL member to be transferred comprises a base member/a first electrode/an electron transporting layer (with a bonding property improving substance added to the light emitting layer and/or the electron transporting layer). The organic EL element is manufactured by transferring the organic EL light emitting layer and the hole transporting layer on the electron transporting layer, and forming the second electrode on the hole transporting layer in the perpendicular direction to the first electrode.

(4) The organic EL transfer member comprises a supporting member/a peeling layer/an organic EL light emitting layer/an electron transporting layer, and the organic EL member to be transferred comprises a base member/a first electrode (with a bonding property improving substance added to the electron transporting layer). The organic EL element is manufactured by transferring the electron transporting layer and the organic EL light emitting layer on the first electrode (cathode) as the active electrode, forming the hole transporting layer on the organic EL light emitting layer, and forming the second electrode (anode) perpendicular to the first electrode thereon.

Hereinafter, an embodiment of a manufacturing method for an organic EL element in the present invention will be explained with reference to the drawings.

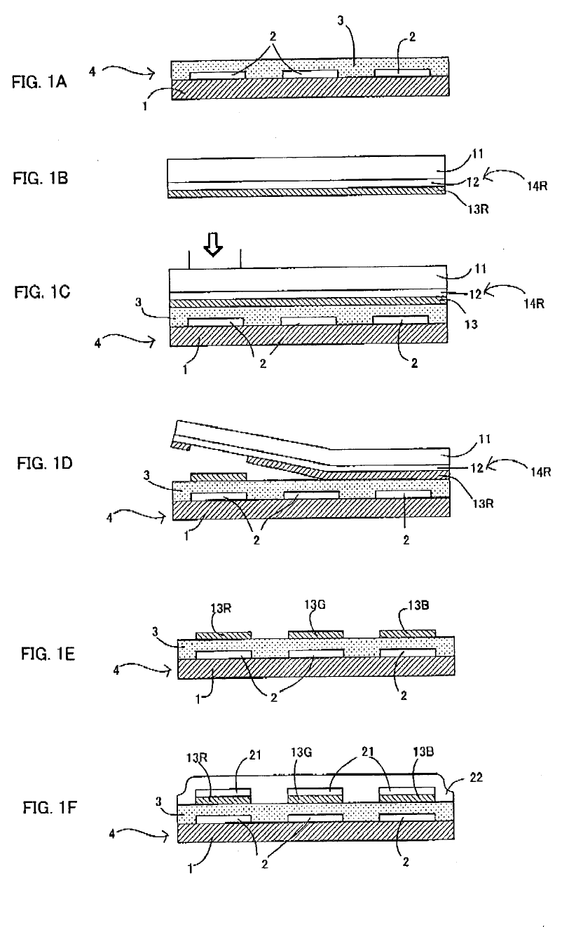

As shown in FIG. 1A, a member to be transferred 4 comprising ITO electrodes 2 formed in a line-like form as passive electrodes on a transparent base member 1 and a hole transporting layer 3 including a bonding property improving substance formed thereon is prepared. On the other hand, as shown in FIG. 1B, a red transfer member 14R comprising a red organic EL light emitting layer 13R provided on a supporting member 11 via a peeling layer 12 is prepared. Similarly, a green transfer member 14G comprising a green organic EL light emitting layer 13G, and a blue transfer member 14B comprising a blue organic EL light emitting layer 13B are prepared. Next, as shown in FIG. 1C, the red light emitting layer 13R side of the red transfer member 14R and the hole transporting layer 3 side of the member to be transferred 4 are superimposed, and only the part to be transferred is closely contacted and heated for transfer. Next, as shown in FIG. 1D, the red transfer member 14R is peeled off. Similarly, by transferring the green light emitting layer 13G using the green transfer member 14G, and transferring the blue light emitting layer 13B using the blue transfer member 14B successively on the member to be transferred 4, the light emitting layers of the three colors including red, green, and blue can be formed on the member to be transferred 4 as shown in FIG. 1E. Thereafter, by forming a cathode 21 and sealing the sealing cans 22 with a UV hardening type resin adhesive, an organic EL color display can be produced as shown in FIG. 1F.

(Close Contact Heating at the Time of the Transfer)

In the manufacturing of an organic EL element of the present invention, close contact heating is carried out at the time of the transfer. For the close contact heating, any of a method of partially heating the area to be transferred, a method of partially contacting closely only the area to be transferred, and a method of partially contacting closely and heating only the area to be transferred can be adopted.

As the means for close contact heating, for example, a thermal head, a heat light source, a laser beam, a heat roll, a thermal press, a means using a patterned mask, a means using them in a combination, or the like can be presented.

In the case a patterned mask is used, for example, a mask selected from the group consisting of a mask comprising an opening part and a rib part, a mask comprising a low heat conductive part and a high heat conductive part, and a mask comprising a part for absorbing a light and generating a heat and a part without light absorption nor heat generation can be used.

As to the heating operation at the time of the transfer, a highly efficient EL element can be manufactured by controlling and adjusting the temperature, the heating speed, and the heating time in a temperature range where only the organic EL transfer layer can be transferred.

Since the organic EL light emitting layer is deteriorated in general by the moisture and the oxygen, it is preferable to carry out the transfer in a dry room with the humidity eliminated as much as possible or a glove box controlled in a nitrogen atmosphere. Moreover, it is also preferable to carry out the transfer of the organic EL transfer layer in a vacuum, and then carry out the vacuum deposition in the vacuum to form an electrode.

Bonding Property Improving Substance:

In the present invention, the transfer temperature can be lowered by introducing a bonding property improving substance in at least one of the uppermost layers of the organic EL transfer member or the member to be transferred so that the organic EL element can be manufactured without deteriorating the light emitting characteristic of the organic EL element or the element lifetime by the heat.

Since the light emitting characteristic may be deteriorated if impurities are introduced in the organic EL light emitting material, in the case the uppermost layer is the organic EL light emitting layer, it is preferable to add the bonding property improving substance to the other uppermost layer, not adding the same in the organic EL light emitting layer. For example, in the case the organic EL transfer member is a supporting member/a peeling layer/an electron injecting layer/an organic EL light emitting layer, and the organic EL member to be transferred is a base member/a first electrode/a hole transporting layer as in the above-mentioned example (1) or the organic EL transfer member is a supporting member/a peeling layer/an organic EL light emitting layer, and the organic EL member to be transferred is a base member/a first electrode/a hole transporting layer as in the above-mentioned example (2), it is preferable to add the bonding property improving substance in the hole transporting layer as the uppermost layer of the member to be transferred without adding the same in the organic EL light emitting layer as the uppermost layer of the member to be transferred.

As such a bonding property improving substance, a material capable of providing the viscous bonding property having the glass transition temperature (Tg) lower than the Tg of the organic EL transfer layer and that of the member to be transferred layer can be used without limitation. The lower the Tg is, the more preferable it is. The Tg is preferably −50° C. to 50° C.

Moreover, it is preferable that the bonding property improving substance in the present invention has a low molecular weight since the viscous bonding property is increased in general, however, in the case it is too low, if the bonding property improving substance is added to, for example, only in the hole transporting layer in the above-mentioned example (1), the bonding property improving substance is moved to the organic EL light emitting layer at the time of the heating operation for the transfer so that the light emitting characteristic may be deteriorated. Therefore, the molecular weight of the bonding property improving substance is preferably 1,000 to 100,000.

Furthermore, as the bonding property improving substance, any of a soluble material in a solvent, an aqueous dispersion material, and a water soluble material can be used. In the case an aqueous dispersion material is used, since the organic EL material film surface is made coarse so as to the element lifetime can be deteriorated if the particle size of the material is coarse, it is preferable that the particle size of the material is fine. In this case, the particle size of the bonding property improving substance is preferably 10 μm or less.

As a material usable as such a bonding property improving substance, for example, the following can be presented.

<Aqueous Dispersion Based Material>

Polyester emulsion; (Baironal series produced by Toyobo Co., Ltd.)

Ionomer emulsion: (Chemipearl series produced by Mitsui Chemicals, Inc.)

Emulsion of a copolymer of an ethylene and a vinyl acetate; (Aquatex series produced by CHIRIKA. Co., ltd.)

<Solvent Based Material>

Copolymer based material of an ethylene and a vinyl acetate (Polychemical EVA150, EVA250 produced by Du Pont-Mitsui Polychemicals Co., Ltd.)

Acrylic polyol based material: (U230-T, SU-28 produced by Soken Chemical & Engineering Co., Ltd.)

The transfer temperature can be lowered according to the combination of the uppermost layer of the transfer member or the uppermost layer of the member to be transferred formed by adding such bonding property improving substance. In particular, in the case a polymer organic EL material is used, since the light emitting characteristic and the element lifetime can be deteriorated if the organic EL material is heated to a temperature of the Tg or higher, and they are further deteriorated at the temperature higher than the rubber elasticity area, it is preferable to select a combination capable of achieving the transfer at the rubber elasticity area of the organic EL material or lower, and it is further preferable to select a combination capable of achieving the transfer at the Tg of the organic EL material or lower.

Organic EL Transfer Member:

(Organic EL Transfer Layer)

The organic EL transfer member of the present invention is provided with a transferable layer comprising at least a light emitting layer including an organic light emitting material, and additionally an optional layer (these layers as a whole are referred to as the organic EL transfer layer). As the layers, for example a layer made of an organic light emitting material to be melted or softened by heating can be presented preferably.

The uppermost layer of the organic EL transfer layer of the present invention is preferably (obligatorily in the case the uppermost layer of the member to be transferred does not include the bonding property improving substance) a layer including the bonding property improving substance preferably to be softened by heating so that the close contact property of the interface is improved. The light emitting characteristic of the organic EL element can be improved by lowering the transfer temperature.

Moreover, it is also preferable to provide a multi layer structure by optionally combining the hole transporting layer, the electron transporting layer, or the like in addition to the light emitting layer. In this case, the uppermost layer may be the hole transporting layer, or the like other than the light emitting layer.

The transfer temperature is changed according to the combination of the uppermost layer of the transfer member and the uppermost layer of the member to be transferred, however, since the organic EL material and the EL element are relatively weak to a high temperature, it is preferable to transfer at a temperature of the Tg of the material or higher and the melting point or lower.

(Supporting Member)

For the supporting member, a material durable to heat is required. Specifically, the Tg of the supporting member is preferably the transfer temperature or higher, however, a supporting member with the heat resistant process applied, such as a PET film with the heat resistant process applied can be employed. Moreover, the supporting member is preferably one with the property of which can coat the peeling layer easily, however, by forming a primer layer on the supporting member, the peeling layer can be coated easily.

(Primer Layer)

A primer layer to be provided on the organic EL transfer member of the present invention may be any layer which can be provided between the supporting member and the peeling layer, made of a material compatible with both the supporting member and the peeling layer, and the peeling layer can be coated on the supporting member easily. Such a primer layer provides, for example, an effect of improving the coating property such as the coating evenness at the time of forming the peeling layer.

(Peeling Layer)

The organic EL transfer member of the present invention can preferably be provided with a peeling layer. As the peeling layer, one to be used ordinarily in transfer can be used. In the case the organic EL transfer layer is made of a solvent based material, it is preferably made of a material selected from water soluble polymers in order to coat the organic EL layer on the peeling layer in production of the organic EL transfer member. As examples thereof, those including a PVA (polyvinyl alcohol) can be presented. However, solvent based polymers can be used as well.

By using a material having a good peeling property to the organic EL transfer layer for the peeling layer, the organic EL transfer layer can be transferred at a relatively low temperature by closely contacting the same with the member to be transferred, in a softened state, so as to produce the EL element.

Preferably, the peeling layer itself may contain a below mentioned light heat converting substance for converting the light into the heat.

As the light heat converting substance, a substance capable of absorbing the light and converting the same efficiently into the heat according to the light source to be used is preferable. For example, in the case a near infrared semiconductor laser is used as the light source, a substance having the absorption band in the infrared ray band is preferable. Specifically, a carbon black, a graphite, a phthalocyanine based pigment, a squarium based pigment, a chroconium based pigment, an azulenium based pigment, anitroso compound and a metal complex salt thereof, a polymethyne based pigment, a dithiol metal complex salt based pigment, a triarl methane based pigment, an indoaniline metal complex pigment, a naphthoquinone based pigment, an anthraquinone based pigment, or the like can be presented.

As a binder to be used with the light heat converting substance, for example, a PVA can be presented. In addition thereto, a resin having a high glass transition point and a high heat conductivity, such as commonly used heat resistant resins including a methyl polymethacrylate, a polycarbonate, a polystyrene, an ethyl cellulose, a nitrocellulose, a polyvinyl chloride, a polyamide, a polyimide, a polyether imide, a polysulfone, and an aramide can be used as well. Among these examples, the water soluble polymers are preferable for their good peeling property to the organic EL transfer layer.

By providing such the light heat converting layer, for example, the laser transfer can be executed easily.

(Light Emitting Layer)

As the organic light emitting material used in the organic EL light emitting layer in the present invention, for example, the following can be presented.

As the pigment based materials, for example, a cyclopentadiene derivative, a tetraphenyl butadiene derivative, a triphenyl amine derivative, an oxadiazol derivative, a pyrazoroquinoline derivative, a distylyl benzene derivative, a distyryl arylene derivative, a silol derivative, a thiophene ring compound, a pyridine ring compound, a perynone derivative, a perylene derivative, an oligothiophene derivative, a trifumanyl amine derivative, an oxadiazol dimmer, a pyrazolyne dimmer, or the like can be presented.

As the metal complex based material, for example, metal complexes having an Al, a Zn, a Be, or the like, or a rare earth metal such as a Tb, an Eu, a Dy as the central metal and an oxadiazol, a thia diazol, a phenyl pyridine, a phenyl benzoimidazol, a quinoline structure, or the like as the ligand, such as an aluminum quinolinol complex, a benzoquinolinol beryllium complex, a benzooxazol zinc complex, a benzothiazol zinc complex, an azomethyl zinc complex, a porphyrin zinc complex, and an europium complex can be presented.

As the polymer based material, for example, a polyparaphenylene vinylene derivative, a polythiophene derivative, a polyparaphenylene derivative, a polysilane derivative, a polyacetylene derivative, or the like, a polyfluorene derivative, a polyvinyl carbazol derivative, the above-mentioned pigments, a metal complex based light emitting material processed to be a polymer, or the like can be presented.

In order to improve the light emitting efficiency, to change the light emitting wavelength, or the like, doping can be executed in the light emitting layer. As the doping material, for example, a perylene derivative, a coumaline derivative, a rubrene derivative, a quinacrydone derivative, a squarium derivative, a porphyrin derivative, a styryl based pigment, a tetracene derivative, a pyrazolyne derivative, a decacyclene, and a phenoxazone can be presented.

Member to be Transferred:

(Member to be Transferred)

The member to be transferred used in the manufacturing method for an organic EL element of the present invention is a member comprising at least a base member and an electrode formed on the above-mentioned base member, capable of providing at last a part of the organic EL element by receiving the transfer from the organic EL transfer member. To the uppermost layer of such a member to be transferred, preferably (obligatorily in the case the uppermost layer of the transfer member does not include the bonding property improving substance) the bonding property improving substance can be introduced. Thereby, the transfer temperature can further be lowered to for example 120° C., improving the close contact property of the interface so as to improve the light emitting characteristic of the organic EL element. Moreover, since the range of transferring the organic EL transfer layer without the risk of transferring the peeling layer and the light heat converting layer together can be widened by the introduction of the bonding property improving substance, the range capable of preferably executing the transfer can be widened so that the transfer can be carried out stably.

(Base Member)

The base member comprising the organic EL element manufactured by the method of the present invention may be made of a transparent material as needed, but it may be made of an opaque material as well.

(First Electrode)

The electrode (first electrode) provided in the member to be transferred of the present invention is not particularly limited as long as it is an electrode used for an ordinary organic EL element, and it may be patterned as needed. Moreover, the electrode provided in the member to be transferred may either be an anode or a cathode, but it is preferable that either of the anode or the cathode is transparent or translucent, the anode is made of a conductive material having a large work function for facilitating injection of the hole, and the cathode is made of a conductive material having a small work function for facilitating injection of the electron. Moreover, a plurality of materials may be mixed. It is preferable that the both electrodes have a resistance as low as possible. In general, a metal material is used, but an organic or inorganic compound may be used as well.

As specific examples of preferable anode materials, an ITO, an indium oxide, and a gold can be presented. As specific examples of preferable cathode materials, a magnesium alloy (MgAg, or the like), an aluminum alloy (AlLi, Alca, AlMg, or the like), a metal calcium and a metal having a small work function can be presented.

Layer which can be provided in the transfer member or the member to be transferred:

(Electron Transporting Layer and Hole Transporting Layer)

The electron transporting layer and the hole transporting layer in this specification represent those in a wide sense. In addition to those commonly referred to as the electron transporting layer and the hole transporting layer, the layers referred to as the electron injecting layer, the hole injecting layer, the buffer layer, or the like are also included. That is, those for actually transporting the charge and the layers for facilitating movement of the charge by providing the difference of the work functions moderately are both included. In the case these layers are at the uppermost layer of the transporting member or the member to be transferred, it is preferable to include the bonding property improving substance. Moreover, these electron transporting layer and hole transporting layer are not particularly limited as long as they are used commonly for the EL element as those disclosed, for example, in the specification of Japanese patent Application No. 9-155284.

The material comprising the above-mentioned layers may be used alone or as a mixture. As to the mixture, a mixture of materials having the same property or a mixture of materials having different properties can either be used. Furthermore, the layer containing these materials may be provided in one layer or in a plurality of layers.

Second Electrode:

In the present invention, one of the electrodes (first electrode) is provided in the member to be transferred, and the other electrode (second electrode) can be formed after the transfer or formed in the transfer member. The electrode is not particularly limited as long as it is one used ordinarily for the organic EL element, and it can be patterned as needed. Moreover, the second electrode may either be an anode or a cathode, but it is preferable that either of the anode and the cathode is transparent or translucent, the anode is made of a conductive material having a large work function for facilitating injection of the hole, and the cathode is made of a conductive material having a small work function for facilitating injection of the electron. Furthermore, a plurality of materials may be mixed. It is preferable that the both electrodes have a resistance as low as possible. In general, a metal material is used, but an organic or inorganic compound may he used as well.

As specific examples of preferable anode materials, an ITO, an indium oxide, and a gold can be presented. As specific examples of preferable cathode materials, a magnesium alloy (MgAg, or the like), an aluminum alloy (AlLi, AlCa, AlMg, or the like), a metal calcium and a metal having a small work function can be presented.

### EXAMPLES

### Example 1

(Production of the Member to be Transferred A)

A member to be transferred A was obtained by providing a patterned Ito on a glass substrate, coating a hole transporting layer (an aqueous dispersion of a poly3,4-ethylene dioxythiophene/polystyrene sulfonate, referred to in the abbreviation as PEDOT/BAYERN P) by spin coating thereon, and drying at 150° C. for 10 minutes.

(Production of the Member to be Transferred B)

A member to be transferred B was obtained by coating a solution containing a PEDOT and a polyester emulsion with the solid component ratio of the both solutions adjusted to 4:1 by spin coating onto a substrate with an ITO as in the case of the member to be transferred A, and drying at 150° C. for 10 minutes.

(Production of the Transfer Member “a”)

A primer layer was formed by coating a CAN OHP primer (produced by INCTEC INC.) by a wire bar #4 as the primer layer on a PET film as a supporting member, and drying at 90° C. for 1 minute in an oven.

Next, a peeling layer was formed by coating a TMRS04 clear liquid (PVA solution, produced by INTEC INC.) as a peeling layer forming solution by a wire bar #4, and drying at 90° C. for 1 minute in an oven.

Thereafter, a transfer member “a” for a green EL light emitting layer was obtained by coating the below-mentioned green EL light emitting layer forming solution by a 100 nm film thickness by spin coating, and drying at 90° C. for 30 minutes.

Similarly, a transfer member “a” for a red EL light emitting layer was obtained by spin coating the below-mentioned red EL light emitting layer forming solution by a 100 nm film thickness. Furthermore, a transfer member “a” for a blue EL light emitting layer was obtained by spin coating the below-mentioned blue EL light emitting layer forming solution by a 100 nm film thickness.

Green EL Light Emitting Layer Forming Solution

Polyvinyl carbazol 7 parts by weight

Light emitting pigment (G) coumaline 60.1 part by weight

Oxadiazol compound 3 parts by weight

Toluene 5,050 parts by weight

Red EL Light Emitting Layer Forming Solution

Polyvinyl carbazol 7 parts by weight

Light emitting pigment (R) Nile red 0.1 part by weight

Oxadiazol compound 3 parts by weight

Toluene 5,050 parts by weight

Blue EL Light Emitting Layer Forming Solution

Polyvinyl carbazol . . . 7 parts by weight

Light emitting pigment (B) beryllene 0.1 part by weight compound . . .

Oxadiazol compound . . . 3 parts by weight

Toluene . . . 5,050 parts by weight

These have the below-mentioned structural formulae. Polyvinyl carbazol (Lot. K81127 produced by Anan Corp. was used) (CH₂—CH)ₙ

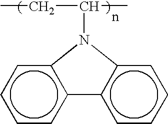

Oxadiazol compound (one produced by Wako Pure Chemical Industries, Ltd. was used)

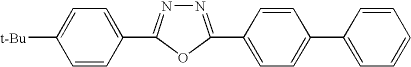

Light emitting pigment (G) coumaline 6 (one produced by Aldrich. Chem. Co. was used)

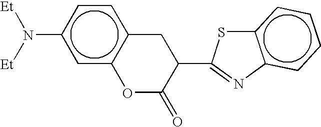

Light emitting pigment (R) Nile red

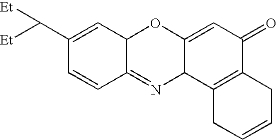

Light emitting pigment (B) beryllene compound

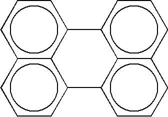

(Transfer Process)

Next, a process for transfer by the transfer member and the member to be transferred contacted closely was executed. At the transfer, a thermal press device was used, and furthermore, a mask (90 μm thickness) made of metal having 80 μm opening parts and 220 μm rib parts, like a shadow mask, was used. With the member to be transferred/the transfer member/the mask superimposed in this order from the bottom so as to be contacted closely, the pressing transfer was executed from above by a thermal press heated to 130° C. Similarly, those produced by the transfer at 150° C. and 200° C. were prepared.

After the pressing, and cooling down the transfer member and the member to be transferred, they were peeled off.

Among those transferred using the member to be transferred A, transfer was not enabled in the one processed at 130° C., and pattern-like transfer was enabled in those processed at 150° C. and 200° C.

As to those transferred using the member to be transferred B, pattern-like transfer was observed even in the one processed at 130° C.

(Production of the Organic EL Element)

Moreover, for those elements, a Ca was vapor deposited by 200 Å and an Ag was vapor deposited by 2,500 Åon the light emitting layer laminated in the pattern of the member to be transferred.

Each element was driven with the ITO and the Ag electrode serving as the address electrodes for examining the light emitting characteristic. The element transferred at 130° C. started the light emission at 3.5V, the element transferred at 150° C. started the light emission at 5.5V, and the element transferred at 200° C. started the light emission at 14V. Accordingly, one transferred at a low temperature has a high value both in the light emission maximum luminance and the efficiency.

### Example 2

Members to be transferred A and B were produced in the same method as in the example 1.

(Production of the Transfer Member “b”)

A primer layer was formed by coating a CAN OHP primer (produced by INTEC INC.) by a wire bar #4 as the primer layer on a PET film as a supporting member, and drying at 90° C. for 1 minute in an oven.

Next, a peeling and light heat converting layer was formed by coating a TMR904 black ink (one having a carbon black added to a TMR 904 produced by INTEC INC.) as a peeling and light heat converting layer forming solution by a wire bar #4, and drying at 90° C. for 1 minute in an oven.

As in the example 1, a transfer member “b” was obtained by coating the organic EL light emitting layer forming solution by spin coating, and thereafter by vacuum drying at 90° C. for 30 minutes.

(Transfer Process)

Next, the transfer member “b” and the member to be transferred were processed for the vacuum close contact by placing the transfer member over the member to be transferred for executing the vacuum suction. Thereafter, a YAG laser was irradiated to the part to be transferred so as to transfer only in the part.

In the case the member to be transferred A was used, with any laser parameter, the organic EL transfer layer was not transferred or the organic EL transfer layer and the peeling and light heat converting layer were transferred together so that a light emitting element was not obtained.

In the case the member to be transferred B was used, transfer of only the EL layer was enabled in a range of 9 to 11A laser current value and in a range of 100 to 200 mm/s laser irradiating speed.

(Production of the Organic EL Element)

Thereafter, a Ca was vapor deposited by 200 Å and an Ag was vapor deposited by 2,500 Å on the light emitting layer laminated in the pattern. Each element was driven with the ITO and the Ag electrode serving as the address electrodes for examining the light emitting characteristic. An element capable of starting the light emission at 2.8V, having a 6,000 cd maximum luminance and a 2 lm/w light emitting efficiency was obtained.

### Example 3

(Production of the Member to be Transferred C)

A member to be transferred C was obtained by forming an ITO in a line-like shape as the passive electrode on a glass substrate, coating a hole transporting layer forming solution containing a bonding property improving substance by a 80 nm film thickness by spin coating thereon, and drying at 150° C. for 10 minutes.

As the hole transporting layer forming solution containing a bonding property improving substance, one prepared by mixing and dispersing an aqueous solution dispersion of a poly3,4-ethylene dioxythiophene/polystyrene sulfonate (referred to in the abbreviation as PEDOT/PSS, product name: Baytron P produced by Bayer Yakuhin, Ltd.) as the hole transporting layer forming solution and an emulsion of a polyester (Baironal: MD1930 produced by Toyobo Co., Ltd.) as the bonding property improving substance by the solid component ratio of 5:2 was used.

(Production of the Member to be Transferred D)

A member to be transferred D was obtained in the same method as in the member to be transferred C except that one prepared by eliminating the bonding property improving substance from the hole transporting layer forming solution containing a bonding property improving substance (a solution of only PEDOT:PSS) was coated by a 80 nm film thickness.

(Production of the Transfer Member c)

A primer layer was formed by coating a CAN OHP primer (produced by INCTEC INC.) by a wire bar #4 on a PET film as a supporting member, and drying at 90° C. for 5 minutes.

Next, a TMR#904 black ink (produced by INCTEC INC.) having a carbon black included in a PVA was coated as a peeling and light heat converting layer by a wire bar #4, and drying at 90° C. for 5 minutes.

Thereafter, a green EL light emitting layer forming solution was spin coated by a 100 nm film thickness so as to obtain a transfer member for a green EL light emitting layer.

Similarly, a blue EL light emitting layer forming solution and a red EL light emitting layer forming solution were spin coated by a 100 nm film thickness so as to obtain transfer members for a blue EL light emitting layer and a red EL light emitting layer.

Green EL Light Emitting Layer Forming Solution

Polyvinyl carbazol 70 parts by weight

Oxadiazol compound 30 parts by weight

Coumaline 61 part by weight

1,2 dichloroethane 3,367 parts by weight

Red EL Light Emitting Layer Forming Solution

Polyvinyl carbazol 70 parts by weight

Oxadiazol compound 30 parts by weight

Nile red 1 part by weight

1,2 dichloroethane 3,367 parts by weight

Blue EL Light Emitting Layer Forming Solution

Polyvinyl carbazol 70 parts by weight

Oxadiazol compound 30 parts by weight

Beryllene compound 1 part by weight

1,2 dichloroethane 3,367 parts by weight

A 1,2 dichloroethane produced by JUNSEI CHEMICAL CO., LTD. was used.

(Transfer Process)

The light emitting layer was patterned by laser transfer using OPC-A001 (λ=790 nm) produced by OPT POWER CORPORATION.

Using large output LD pulse modulation driving device ALP-7402PA (produced by Asahi Data System Corp.), an XY stage, or the like in combination with the laser device, and a software developed by ourselves, a laser beam was controlled such that the laser can be irradiated to a part to be laser-transferred (the XY stage was driven by the control by the software, and the laser irradiating part and the laser irradiating amount were controlled by way of driving the laser pulse drive so as to enable transfer onto the pattern to be transferred).

For closely contacting the transfer member and the member to be transferred, a glass vacuum jig using a vacuum pump was produced so that the inside of the jig can be vacuum suctioned by the vacuum pump with the transfer member and the member to be transferred clamped by the jig.

By irradiating a laser in a line-like from the transfer member side of the transfer member and the member to be transferred to the green light emitting layer forming part, the blue light emitting layer forming part and the red light emitting layer forming part, in turn, by the control by the software, line patterns were provided.

(Production of the Organic EL Element)

Thereafter, a Ca was vapor deposited by 100 Å and an Ag was vapor deposited by 3,000 Å on the light emitting layer laminated in the pattern. Each element was driven by the ITO and the Ag electrode for examining the light emitting characteristic. An element capable of starting the light emission at 2.5V, having a 10,000 cd maximum luminance and a 2.5 lm/W light emitting efficiency maximum value was obtained.

What is claimed is:

1. A manufacturing method for an organic EL element:
using a transfer member having at least a supporting member and a light emitting layer formed peelably on the supporting member and
a member to be transferred having at least a base member and an electrode formed on the base member,
comprising a process of superimposing the light emitting layer side of the transfer member and the electrode side of the member to be transferred, and partially transferring at least the light emitting layer from the transfer member onto the member to be transferred,
wherein a bonding property improving substance is included in at least one of the layer of the transfer member in contact with the member to be transferred or the layer of the member to be transferred in contact with the transfer member.

2. The manufacturing method for an organic EL element according to claim 1, wherein the layer including the bonding property improving substance is a hole transporting layer, an electron transporting layer or a light emitting layer formed at least in one of the transfer member or the member to be transferred.

3. The manufacturing method for an organic EL element according to claim 1, wherein an electron transporting layer or a hole transporting layer is formed between the supporting member and the light emitting layer.

4. A transfer member having at least a supporting member and a light emitting layer formed peelably on the supporting member, wherein a bonding property improving substance is included in the layer of the transfer member to be contacted with a member to be transferred.

5. The transfer member according to claim 4, wherein the layer including the bonding property improving substance is a hole transporting layer, an electron transporting layer or a light emitting layer.

6. A member to be transferred having at least a base member and an electrode formed on the base member, wherein a bonding property improving substance is included in the layer of the member to be transferred to be contacted with a transfer member.

7. The member to be transferred according to claim 6, wherein the layer including the bonding property improving substance is a hole transporting layer or an electron transporting layer.
